(19) United States
(12) Patent Application Publication
(10) Pub. No.: US 2025/0109501 A1
(43) Pub. Date: Apr. 3, 2025

(54) ATOMIC LAYER ETCHING OF METALS USING NOVEL CO-REACTANTS AS HALOGENATING AGENTS

(71) Applicants: Merck Patent GmbH, Darmstadt (DE); North Carolina State University, Raleigh, NC (US)

(72) Inventors: Ravindra KANJOLIA, North Andover, MA (US); Jacob WOODRUFF, Lexington, MA (US); Mansour MOINPOUR, San Jose, CA (US); Charles DEZELAH, Helsinki (FI); Holger SAARE, Raleigh, NC (US); Wenyi XIE, Elmhurst, NY (US); Gregory PARSONS, Raleigh, NC (US); Martin MCBRIARTY, San Jose, CA (US)

(21) Appl. No.: 18/728,534

(22) PCT Filed: Feb. 1, 2023
(86) PCT No.: PCT/US2023/061709

§ 371 Date: Jul. 12, 2024

Related U.S. Application Data
(60) Provisional application No. 63/267,499, filed on Feb. 3, 2022.

(51) Int. Cl. C23F 1/12

(52) U.S. Cl. CPC C23F 1/12

(57) ABSTRACT

The disclosed and claimed subject matter relates to thermal atomic layer etch (ALE) processing of metals and alloys thereof (e.g., cobalt and cobalt alloys) using thionyl chloride (SOCl₂) or a combination of thionyl chloride and pyridine.

### BACKGROUND

### Field

The disclosed and claimed subject matter relates to thermal ALE processing of metals and alloys thereof (e.g., cobalt and cobalt alloys) using thionyl chloride (SOCl₂) or a combination of thionyl chloride and pyridine.

### Related Art

The miniaturization of features in the semiconductor industry is the main factor behind the continuous performance increase of devices. This trend is expected to continue for at least a few more generations of computer chips. Several technical challenges need to be successfully solved for this trend to continue.

Atomic Layer Deposition (ALD) is one technique finding increased application in the semiconductor industry and it currently is the deposition method allowing the best control on the amount of material deposited. In ALD, a layer of atoms is deposited on all surfaces that are exposed to a precursor in the gas phase—this layer is at most as thick as the thickness of one atomic layer. By sequentially exposing the surfaces to two different precursors, a layer of material with the desired thickness will be deposited. The archetypical example of such a process is the deposition of aluminum oxide (Al₂O₃) from trimethylaluminum (TMA, Al(CH₃)₃) and water (H₂O), where methane (CH₄) is eliminated from the two reacting species. The coating of thin and narrow vias and other high aspect ratio features has been demonstrated numerous times by ALD in the literature.

Atomic Layer Etching (ALE or ALEt) can be viewed as the layer-by-layer subtraction of material when ALD is the layer-by-layer addition of material. In ALE, a layer of atoms is removed from all surfaces that are exposed to a precursor in the gas phase—this layer is ideally also at most as thick as the thickness of one atomic layer. ALE is performed by sequentially exposing the surfaces to at least two different precursors, a 1^{st} precursor that activates a layer of surface atoms and a 2^{nd} precursor that promotes the sublimation of this activated layer of atoms; sometimes a 3^{rd} precursor or other additional process steps are used to regenerate the surface to the condition where the 1^{st} precursor will be active.

Careful removal of materials is critical to create transistor and memory devices with sub-10 nm features. In this regard, ALE allows precise removal of materials by using sequential and self-limiting half-reaction steps. The key half-reactions during ALE includes an “activation” step, often using a halogenating reagent to modify the surface being etched, followed by a “removal” step, volatilizing the modified surface layer. Plasma based ALE uses plasma activation to promote anisotropic etching of different materials, including Si, Si₃N₄, SiO₂ and Al₂O₃. See, e.g., Carver et al., ECS J. Solid State Sci. Technol., 4, N5005 (2015); Kanarik et al., J. Phys. Chem. Lett., 9, 4814 (2018); and Kanarik et al., J. Vac. Sci. Technol. A Vacuum, Surfaces, Film., 33, 020802 (2015). For example, Si ALE proceeds via Cl₂ plasma exposure to form a surface passivating layer of SiClₓ which was then removed upon Ar+ ion bombardment. See Kanarik et al., J. Vac. Sci. Technol. A Vacuum, Surfaces, Film., 33, 020802 (2015). However, even with careful control on the bias power during ion bombardment, repeated exposure of energetic species could lead to change in surface composition and damage of device structure. See Gu et al., IEEE Electron Device Lett., 15, 48 (1994). In thermal based ALE, thermally activated reactions enable isotropic etching of various materials including Al₂O₃, HfO₂, ZrO₂, TiO₂, TiN, SiO₂ and Si₃N₄. See, e.g., Abdulagatov et al., JUSTA, 38, 1 (2020); Lee et al., ECS J. Solid State Sci. Technol., 4, N5013 (2015); Lemaire et al., Chem. Mater., 29, 6653 (2017); Abdulagatov et al., Chem. Mater. 30, acs. chemmater.8b02745 (2018); Lee et al., J. Vac. Sci. Technol. A, 36, 061504 (2018); and Lee et al., Chem. Mater., 29, 8202 (2017). Thermal ALE processes for compound materials such as metal oxides generally involve surface fluorination with HF, followed by removal of the surface fluoride layer via ligand exchange reaction with Sn(acac)₂, TMA, DMAC, or BCl₃. See, e.g., Lemaire et al., Chem. Mater., 29, 6653 (2017); Lee et al., J. Vac. Sci. Technol. A, 36, 061504 (2018); Lee et al., Chem. Mater., 27, 3648 (2015); George et al., ACS Nano, 10, 4889 (2016); and Lee et al., Chem. Mater., 28, 7657 (2016).

Although Cl₂ and HF are prevalently used in ALE processing, their gaseous state and/or highly corrosive and toxic nature make them difficult to handle safely. In addition, since HF is a highly polar molecule, it tends to stick to the inner walls of the reactor chamber during processing, so long extended purge times are needed to ensure elimination. See, e.g., Xie et al., J. Vac. Sci. Technol. A, 022605 (2020). Therefore, ALE processes that do not rely on HF are highly advantageous for implementation.

Cobalt (Co) and its alloys are considered promising materials for use in magnetic random access memory (MRAM) devices, as well as in the middle-of-line (MOL) and back-end-of-line (BEOL) processing of semiconductor logic and memory devices; however, to the best of our knowledge, there is currently limited work discussing thermal ALE of Co. Konh et al. and Wang et al. reported a thermal ALE mechanism that involved chlorination of Co using Cl₂(g) to form CoClₓ(s), followed by volatilization with hexafluoroacetylacetone (Hhfac), forming Co(Hfac)ₓCl_{y} as the volatile product. See Konh et al., J. Vac. Sci. Technol. A 021004 (2019); Wang et al., JVSTA 38 (2020) 022611. Lin et al. demonstrated the dissolution of gold in a liquid mixture consisting of 3:1 v/v SOCl₂ to pyridine, which was also effective for dissolving silver, gold, palladium copper, nickel and iron. Specifically, Lin et al. revealed that the dissolution of gold was due to pyridine activating SOCl₂ therefore promoting the conversion of gold into gold chloride, while SOCl₂ or pyridine alone did not cause any dissolution. See Lin et al., Angew. Chemie Int. Ed., No. 49, 7929-7932. https://doi.org/10.1002/anie.201001244 (2010).

In the disclosed and claimed subject matter, either thionyl chloride or the combination of thionyl chloride (SOCl₂) and pyridine is used as a surface chlorinating reagent for thermal ALE of metals. For example, in some embodiments cobalt was successfully etched using thionyl chloride (SOCl₂) and pyridine as a chlorinating agent and hexafluoroacetylacetone (Hhfac) as a volatizing agent. In contrast, other known surface chlorination agents such as BCl₃, TiCl₄, AlCl₃, or Al(CH₃)₂Cl (DMAC) did not evidence comparable success.

### SUMMARY

In one embodiment, the disclosed and claimed subject matter relates to a method for thermal ALE processing of metals and alloys thereof (collectively “metal”). The method generally includes (i) forming a chlorinated metal-containing layer on a surface of a metal by exposing the surface to a chlorinating agent, (ii) conducting a first purge to remove any excess chlorinating agent and/or reaction products, (iii) forming a volatile etch product on the surface of the metal by exposing the chlorinated metal-containing layer to at least one volatilizing agent, and (iv) conducting a second purge to remove the resulting volatile etch products. In a further aspect of this embodiment, the method includes a step (iA) forming a chlorinating agent that is used in step (i). In a further aspect, the method consists essentially of steps (i), (ii), (iii) and (iv). In a further aspect, the method consists of steps (i), (ii), (iii) and (iv). In a further aspect, the method consists essentially of steps (iA) (i), (ii), (iii) and (iv). In a further aspect, the method consists of steps (iA) (i), (ii), (iii) and (iv).

In one aspect of this embodiment, the disclosed and claimed subject matter relates to thermal ALE processing of metals and alloys thereof (collectively “metal”). Suitable metals include, but are not limited to cobalt, nickel, copper, molybdenum, ruthenium, tungsten and alloys including the same.

In another aspect of this embodiment, the step (i) chlorinated metal-containing layer has the formula CoClₓ(s) where x=a value from about 1 to about 2.

In another aspect of this embodiment, the step (iii) at least one volatizing agent includes one or more of formic acid, acetylacetone (Hacac), and/or hexafluoroacetylacetone (Hhfac).

In another aspect of this embodiment, the step (iii) at least one volatizing agent includes hexafluoroacetylacetone (Hhfac).

In another aspect of this embodiment, the step (iii) volatile etch product has the formula CoClₓHfac_{y}(g) where x=0 or 1, and y=1 or 2.

In a further aspect of this embodiment, formation of the step (iii) volatile etch product produces a further byproduct. In one aspect, the further byproduct includes HCl(g). In one aspect, the further byproduct includes Cl₂(g). In one aspect, the further byproduct includes S₂Cl₂(g). In one aspect, the further byproduct includes SO₂(g).

In a further aspect of this embodiment, step (i) is performed at a temperature between about 140° C. and about 325° C.

In a further aspect of this embodiment, step (iii) is performed at a temperature between about 140° C. and about 325° C.

In a further aspect of this embodiment, step (i) and step (iii) are each performed at about the same temperature. In a further aspect of this embodiment, step (i) and step (iii) are each performed at the same temperature. In a further aspect of this embodiment, step (i) and step (iii) are each performed at a different temperature.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the changes in the delta parameter (Δ) measured at 635 nm from in situ spectroscopic ellipsometry for Co samples exposed to 30 sub-doses SOCl₂, 20 sub-doses of pyridine and 20 sub-doses of SOCl₂-Py at 250° C.;

FIG. 2 illustrates the changes in the delta parameter (Δ) measured at 635 nm from in situ spectroscopic ellipsometry for Co samples exposed to 30 sub-doses of BCl₃, TiCl₄, AlCl₃ and Al(CH₃)₂Cl at 250° C.; and

FIG. 3 illustrates XPS scans of (a) Co 2p and (b) Ta 4f regions for as-received Co and Co after 2, 4, 6 and 8 etch cycles at 250° C. where each etch cycle followed the exposure sequence of 6(0.4 s)/6(0.2 s Hhfac). The Ta 4f signal is from a thin layer of tantalum nitride (TaN) on which Co was deposited.

### DEFINITIONS

Unless otherwise stated, the following terms used in the specification and claims shall have the following meanings for this application.

For purposes of the disclosed and claimed subject matter, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds., The Royal Society of Chemistry: Cambridge, 2009; Chapter 1, pp. 1-36.

Throughout the description, the terms Atomic Layer Etching or ALE refer to a process including, but is not limited to, the following processes: (i) sequentially introducing each reactant, including the SOCl₂ or SOCl₂+pyridine mixture and Hhfac, into a reactor such as a single wafer ALE reactor, semi-batch ALD reactor, or batch furnace ALE reactor; (ii) exposing a substrate to each reactant, including the SOCl₂ or SOCl₂+pyridine mixture and Hhfac, by moving or rotating the substrate to different sections of the reactor where each section is separated by inert gas curtain, i.e., spatial ALD/ALE reactor or roll to roll ALD/ALE reactor.

As used herein, the term “feature” refers to an opening in a substrate which may be defined by one or more sidewalls, a bottom surface, and upper corners. In various aspects, the feature may be a via, a trench, contact, dual damascene, etc.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

The disclosed and claimed precursors are preferably substantially free of water. As used herein, the term “substantially free” as it relates to water, means less than 5000 ppm (by weight) measured by proton NMR or Karl Fischer titration, preferably less than 3000 ppm measured by proton NMR or Karl Fischer titration, and more preferably less than 1000 ppm measured by proton NMR or Karl Fischer titration, and most preferably less than 100 ppm measured by proton NMR or Karl Fischer titration.

The disclosed and claimed precursors are also preferably substantially free of metal ions or metals such as, Li⁺ (Li), Na⁺ (Na), K⁺ (K), Mg²⁺ (Mg), Ca²⁺ (Ca), Al³⁺ (Al), Fe²⁺ (Fe), Fe³⁺ (Fe), Ni²⁺ (Ni), Cr³⁺ (Cr), titanium (Ti), vanadium (V), manganese (Mn), cobalt (Co), nickel (Ni), copper (Cu) or zinc (Zn). These metal ions or metals are potentially present from the starting materials/reactor employed to synthesize the precursors. As used herein, the term “substantially free” as it relates to Li, Na, K, Mg, Ca, Al, Fe, Ni, Cr, Ti, V, Mn, Co, Ni, Cu or Zn means less than 5 ppm (by weight), preferably less than 3 ppm, and more preferably less than 1 ppm, and most preferably 0.1 ppm as measured by ICP-MS.

Unless otherwise indicated, “alkyl” refers to a C₁ to C₂₀ hydrocarbon groups which can be linear, branched (e.g., methyl, ethyl, propyl, isopropyl, tert-butyl and the like) or cyclic (e.g., cyclohexyl, cyclopropyl, cyclopentyl and the like). These alkyl moieties may be substituted or unsubstituted as described below. The term “alkyl” refers to such moieties with C₁ to C₂₀ carbons. It is understood that for structural reasons linear alkyls start with C₁, while branched alkyls and linear start with C₃. Moreover, it is further understood that moieties derived from alkyls described below, such as alkyloxy and perfluoroalkyl, have the same carbon number ranges unless otherwise indicated. If the length of the alkyl group is specified as other than described above, the above-described definition of alkyl still stands with respect to it encompassing all types of alkyl moieties as described above and that the structural consideration with regards to minimum number of carbons for a given type of alkyl group still apply.

Halo or halide refers to a halogen, F, Cl, Br or I which is linked by one bond to an organic moiety. In some embodiments, the halogen is F. In other embodiments, the halogen is Cl.

Halogenated alkyl refers to a C₁ to C₂₀ alkyl which is fully or partially halogenated.

Perfluoroalkyl refers to a linear, cyclic or branched saturated alkyl group as defined above in which the hydrogens have all been replaced by fluorine (e.g., trifluoromethyl, perfluoroethyl, perfluoropropyl, perfluorobutyl, perfluoroisopropyl, perfluorocyclohexyl and the like).

The disclosed and claimed precursors are preferably substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the precursors preferably have purity of 98 wt. % or higher, more preferably 99 wt. % or higher as measured by GC when used as precursor to deposit the ruthenium-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

In one embodiment, the disclosed and claimed subject matter relates to a method for thermal ALE processing of metals and alloys thereof (collectively “metal”). The method generally includes (i) forming a chlorinated metal-containing layer on a surface of a metal by exposing the surface to a chlorinating agent, (ii) conducting a first purge to remove any excess chlorinating agent and/or reaction products, (iii) forming a volatile etch product on the surface of the metal by exposing the chlorinated metal-containing layer to at least one volatilizing agent, and (iv) conducting a second purge to remove the resulting volatile etch products. In a further aspect of this embodiment, the method includes a (iA) forming a chlorinating agent that is used in step (i). In a further aspect, the method consists essentially of steps (i), (ii), (iii) and (iv). In a further aspect, the method consists of steps (i), (ii), (iii) and (iv). In a further aspect, the method consists essentially of steps (iA) (i), (ii), (iii) and (iv). In a further aspect, the method consists of steps (iA) (i), (ii), (iii) and (iv).

Specific aspects of the disclosed and claimed subject matter are exemplified below.

### Metals

As discussed above, the disclosed and claimed subject matter relates to thermal ALE processing of metals and alloys thereof (collectively “metal”). Suitable metals include, but are not limited to cobalt, nickel, copper, molybdenum, ruthenium, tungsten and alloys including the same.

In one embodiment, the metal includes cobalt (Co).

In one embodiment, the metal includes nickel (Ni).

In one embodiment, the metal includes copper (Cu).

In one embodiment, the metal includes molybdenum (Mo).

In one embodiment, the metal includes ruthenium (Ru).

In one embodiment, the metal includes tungsten (W).

### Chlorinating Agent

As discussed above, the chlorinating agent of the disclosed and claimed subject matter is thionyl chloride (SOCl₂) or the reaction product of thionyl chloride and pyridine. Without being bound by theory it is believed that the pyridine activates thionyl chloride to chlorinate metals more effectively by forming a reactive adduct with thionyl chloride.

In one embodiment, the disclosed and claimed method includes step a (iA) forming a chlorinating agent that is used in step (i). In step (iA), the chlorinating agent is formed by mixing thionyl chloride (SOCl₂) with pyridine and which is then used in step (i). In one aspect of this embodiment, thionyl chloride (SOCl₂) and pyridine are mixed together to form a chlorinating agent before being used in step (i). In another aspect of this embodiment, the thionyl chloride (SOCl₂) and pyridine are mixed together in situ during step (i). In this aspect, the surface of the metal to be treated with the chlorinating agent in step (i) is sequentially exposed to one of the thionyl chloride (SOCl₂) and pyridine followed by the other of the thionyl chloride (SOCl₂) and pyridine.

### Chlorinated Metal-Containing Layer

As discussed above, step (i) of the disclosed and claimed subject matter includes reacting the chlorinating agent with the surface of the metals to form a chlorinated metal-containing layer on the surface. As those skilled in the art will recognize, the nature of the chlorinated metal depends upon the metal being treated. In one embodiment, for example, where the metal includes cobalt, the chlorinated metal of the chlorinated metal-containing layer has the formula CoClₓ(s) where x=a value from about 1 to about 2.

### Volatizing Agent

In another aspect of this embodiment, the step (iii) at least one volatizing agent includes one or more of hexafluoroacetylacetone (Hhfac), acetylacetone (Hacac) and formic acid. In one aspect of this embodiment, the at least one volatizing agent includes hexafluoroacetylacetone (Hhfac). In one aspect of this embodiment, the at least one volatizing agent includes acetylacetone (Hacac). In one aspect of this embodiment, the at least one volatizing agent includes formic acid.

In another aspect of this embodiment, the step (iii) volatile etch product has the formula CoClₓHfac_{y}(g) where x=0 or 1 and y=1 or 2. In one aspect of this embodiment, the step (iii) volatile etch product has the formula CoCl (hfac). In one aspect of this embodiment, the step (iii) volatile etch product has the formula Co(hfac)₂.

### Temperatures

As discussed above, step (i) of the disclosed and claimed subject matter is performed at an elevated temperature. In one embodiment step (i) is performed at temperature between about 100° C. and about 350° C. In one embodiment step (i) is performed at temperature between about 100° C. and about 200° C. In one embodiment step (i) is performed at temperature between about 140° C. and about 325° C. In one embodiment step (i) is performed at temperature between about 140° C. and about 300° C. In one embodiment step (i) is performed at temperature between about 140° C. and about 275° C. In one embodiment step (i) is performed at temperature between about 150° C. and about 300° C. In one embodiment step (i) is performed at temperature between about 150° C. and about 275° C. In one embodiment step (i) is performed at temperature between about 175° C. and about 275° C. In one embodiment step (i) is performed at temperature between about 200° C. and about 275° C. In one embodiment step (i) is performed at temperature between about 225° C. and about 275° C. In one embodiment step (i) is performed at temperature between about 200° C. and about 250° C. In one embodiment step (i) is performed at temperature of about 100° C. In one embodiment step (i) is performed at temperature of about 110° C. In one embodiment step (i) is performed at temperature of about 120° C. In one embodiment step (i) is performed at temperature of about 130° C. In one embodiment step (i) is performed at temperature of about 140° C. In one embodiment step (i) is performed at temperature of about 150° C. In one embodiment step (i) is performed at temperature of about 160° C. In one embodiment step (i) is performed at temperature of about 170° C. In one embodiment step (i) is performed at temperature of about 180° C. In one embodiment step (i) is performed at temperature of about 190° C. In one embodiment step (i) is performed at temperature of about 200° C. In one embodiment step (i) is performed at temperature of about 210° C. In one embodiment step (i) is performed at temperature of about 220° C. In one embodiment step (i) is performed at temperature of about 230° C. In one embodiment step (i) is performed at temperature of about 240° C. In one embodiment step (i) is performed at temperature of about 250° C. In one embodiment step (i) is performed at temperature of about 260° C. In one embodiment step (i) is performed at temperature of about 270° C. In one embodiment step (i) is performed at temperature of about 280° C. In one embodiment step (i) is performed at temperature of about 290° C. In one embodiment step (i) is performed at temperature of about 300° C. In one embodiment step (i) is performed at temperature of about 310° C. In one embodiment step (i) is performed at temperature of about 320° C. In one embodiment step (i) is performed at temperature of about 325° C. In one preferred embodiment, step (i) is performed at temperature of about 350° C.

As discussed above, step (iii) of the disclosed and claimed subject matter is performed at an elevated temperature. In one embodiment step (iii) is performed at temperature between about 100° C. and about 350° C. In one embodiment step (iii) is performed at temperature between about 100° C. and about 200° C. In one embodiment step (iii) is performed at temperature between about 140° C. and about 350° C. In one embodiment step (iii) is performed at temperature between about 140° C. and about 325° C. In one embodiment step (iii) is performed at temperature between about 140° C. and about 300° C. In one embodiment step (iii) is performed at temperature between about 140° C. and about 275° C. In one embodiment step (iii) is performed at temperature between about 150° C. and about 300° C. In one embodiment step (iii) is performed at temperature between about 150° C. and about 275° C. In one embodiment step (iii) is performed at temperature between about 175° C. and about 275° C. In one embodiment step (iii) is performed at temperature between about 200° C. and about 275° C. In one embodiment step (iii) is performed at temperature between about 225° C. and about 275° C. In one embodiment step (iii) is performed at temperature between about 200° C. and about 250° C. In one embodiment step (iii) is performed at temperature of about 100° C. In one embodiment step (iii) is performed at temperature of about 110° C. In one embodiment step (iii) is performed at temperature of about 120° C. In one embodiment step (iii) is performed at temperature of about 130° C. In one embodiment step (iii) is performed at temperature of about 140° C. In one embodiment step (iii) is performed at temperature of about 150° C. In one embodiment step (iii) is performed at temperature of about 160° C. In one embodiment step (iii) is performed at temperature of about 170° C. In one embodiment step (iii) is performed at temperature of about 180° C. In one embodiment step (iii) is performed at temperature of about 190° C. In one embodiment step (iii) is performed at temperature of about 200° C. In one embodiment step (iii) is performed at temperature of about 210° C. In one embodiment step (iii) is performed at temperature of about 220° C. In one embodiment step (iii) is performed at temperature of about 230° C. In one embodiment step (iii) is performed at temperature of about 240° C. In one embodiment step (iii) is performed at temperature of about 250° C. In one embodiment step (iii) is performed at temperature of about 260° C. In one embodiment step (iii) is performed at temperature of about 270° C. In one embodiment step (iii) is performed at temperature of about 280° C. In one embodiment step (iii) is performed at temperature of about 290° C. In one embodiment step (iii) is performed at temperature of about 300° C. In one embodiment step (iii) is performed at temperature of about 310° C. In one embodiment step (iii) is performed at temperature of about 320° C. In one embodiment step (iii) is performed at temperature of about 325° C. In one preferred embodiment, step (iii) is performed at temperature of about 350° C.

In one embodiment, step (i) and step (iii) are each performed at about the same temperature. In a further aspect of this embodiment, step (i) and step (iii) are each performed at the same temperature. In another embodiment, step (i) and step (iii) are each performed at a different temperature.

### Cycles

As those skilled in the art will appreciate, steps (i) and (iii) of the disclosed and claimed subject matter are conducted in cycles in order to achieve a desired degree of etch. A single cycle of the disclosed and claimed method includes:

(step (i))ₙ+(step (iii))ₘ

where n and m each independently=1-20 and represent the number of times (i.e., the number of iterations) that step (i) and step (iii) are each performed within a single cycle. As those skilled in the art will understand, the disclosed and claimed process will include a purge step (ii) when proceeding from step (i) to step (iii) as well as an additional purge step (iv) before beginning a new cycle (i.e., proceeding from step (iii) to step (i)). However, purge steps do not have to be performed between iterations of a single step (e.g., between multiple iterations of step (i) or between multiple iterations of step (iii)). Thus, a single cycle is to be understood as beginning when the first iteration of step (i) is performed and ending when the last purge step (iv) is performed before another iteration of step (i) is performed again regardless of the number of purging steps conducted during the process.

In one embodiment, n and m are the same.

In one embodiment, n and m are different.

In one embodiment, n is the same as m. In one embodiment, n is different from m.

In one embodiment n=1. In one embodiment n=2. In one embodiment n=3. In one embodiment n=4. In one embodiment n=5. In one embodiment n=6. In one embodiment n=7. In one embodiment n=8. In one embodiment n=9. In one embodiment n=10. In one embodiment n=11. In one embodiment n=12. In one embodiment n=13. In one embodiment n=14. In one embodiment n=15. In one embodiment n=16. In one embodiment n=17. In one embodiment n=18. In one embodiment n=19. In one embodiment n=20.

In one embodiment m=1. In one embodiment m=2. In one embodiment m=3. In one embodiment m=4. In one embodiment m=5. In one embodiment m=6. In one embodiment m=7. In one embodiment m=8. In one embodiment m=9. In one embodiment m=10. In one embodiment m=11. In one embodiment m=12. In one embodiment m=13. In one embodiment m=14. In one embodiment m=15. In one embodiment m=16. In one embodiment m=17. In one embodiment m=18. In one embodiment m=19. In one embodiment m=20.

In one embodiment n=1 and m=1. In one embodiment n=2 and m=2. In one embodiment n=3 and m=3. In one embodiment n=4 and m=4. In one embodiment n=5 and m =5. In one embodiment n=6 and m=6. In one embodiment n=7 and m=7. In one embodiment n=8 and m=8. In one embodiment n=9 and m=9. In one embodiment n=10 and m=10. In one embodiment n=11 and m=11. In one embodiment n=12 and m=12. In one embodiment n=13 and m=13. In one embodiment n=14 and m=14. In one embodiment n=15 and m=15. In one embodiment n=16 and m=16. In one embodiment n=17 and m=17. In one embodiment n=18 and m=18. In one embodiment n=19 and m=19. In one embodiment n=20 and m=20.

In one embodiment, each iteration of step (i) alternates with an iteration of step (iii) within each cycle (i.e., alternating between each iteration of step (i) with an iteration of step (iii)). In another embodiment, all iterations of step (i) are begun and completed before the iterations of step (iii) are begun and completed within in each cycle.

### Number of Cycles

The disclosed and claimed process can include any number of desired cycles. In one embodiment, the number of cycles is from about 10 to about 5000. In one embodiment, the number of cycles is from about 10 to about 1000. In one embodiment, the number of cycles is from about 50 to about 2500. In one embodiment, the number of cycles is from about 50 to about 1500. In one embodiment, the number of cycles is from about 50 to about 1000. In one embodiment, the number of cycles is from about 50 to about 750. In one embodiment, the number of cycles is from about 50 to about 500. In one embodiment, the number of cycles is from about 50 to about 300. In one embodiment, the number of cycles is from about 50 to about 200. In one embodiment, the number of cycles is from about 10 to about 50. In one embodiment, the number of cycles is from about 150 to about 4000. In one embodiment, the number of cycles is from about 200 to about 3000. In one embodiment, the number of cycles is from about 250 to about 2500. In one embodiment, the number of cycles is from about 350 to about 2000. In one embodiment, the number of cycles is from about 450 to about 1700. In one embodiment, the number of cycles is from about 500 to about 1500. In one embodiment, the number of cycles is from about 750 to about 1250. In one embodiment, the number of cycles is from about 250 to about 1000. In one embodiment, the number of cycles is from about 500 to about 1000. In one embodiment, the number of cycles is from about 750 to about 1000.

In one embodiment, the number of cycles is about 10. In one embodiment, the number of cycles is about 20. In one embodiment, the number of cycles is about 30. In one embodiment, the number of cycles is about 40. In one embodiment, the number of cycles is about 50. In one embodiment, the number of cycles is about 100. In one embodiment, the number of cycles is about 125. In one embodiment, the number of cycles is about 150. In one embodiment, the number of cycles is about 175. In one embodiment, the number of cycles is about 200. In one embodiment, the number of cycles is about 250. In one embodiment, the number of cycles is about 300. In one embodiment, the number of cycles is about 350. In one embodiment, the number of cycles is about 400. In one embodiment, the number of cycles is about 450. In one embodiment, the number of cycles is about 500. In one embodiment, the number of cycles is about 750. In one embodiment, the number of cycles is about 1000. In one embodiment, the number of cycles is about 1250. In one embodiment, the number of cycles is about 1500. In one embodiment, the number of cycles is about 1750. In one embodiment, the number of cycles is about 2000. In one embodiment, the number of cycles is about 2250. In one embodiment, the number of cycles is about 2500. In one embodiment, the number of cycles is about 2750. In one embodiment, the number of cycles is about 3000. In one embodiment, the number of cycles is about 3250. In one embodiment, the number of cycles is about 3500. In one embodiment, the number of cycles is about 4000. In one embodiment, the number of cycles is about 4500. In one embodiment, the number of cycles is about 5000.

### Time

In one embodiment of the disclosed and claimed subject matter, each iteration of step (i) can take between about 0.1 seconds and about 60 seconds. In one embodiment of the disclosed and claimed subject matter, each iteration of step (i) can take between about 20 seconds and about 60 seconds. In one embodiment of the disclosed and claimed subject matter, each iteration of step (i) can take between about 5 seconds and about 20 seconds. In one embodiment of the disclosed and claimed subject matter, each iteration of step (i) can take between about 1 second and about 5 seconds. In one embodiment, each iteration of step (i) can take between about 0.2 seconds and about 0.9 second. In one embodiment, each iteration of step (i) can take between about 0.3 seconds and about 0.8 second. In one embodiment, each iteration of step (i) can take between about 0.4 seconds and about 0.7 second. In one embodiment, each iteration of step (i) takes about 0.1 seconds. In one embodiment, each iteration of step (i) takes about 0.2 seconds. In one embodiment, each iteration of step (i) takes about 0.3 seconds. In one embodiment, each iteration of step (i) takes about 0.4 seconds. In one embodiment, each iteration of step (i) takes about 0.5 seconds. In one embodiment, each iteration of step (i) takes about 0.6 seconds. In one embodiment, each iteration of step (i) takes about 0.7 seconds. In one embodiment, each iteration of step (i) takes about 0.8 seconds. In one embodiment, each iteration of step (i) takes about 0.9 seconds. In one embodiment, each iteration of step (i) takes about 1 second. In one embodiment, each iteration of step (i) takes about 2 seconds. In one embodiment, each iteration of step (i) takes about 3 seconds. In one embodiment, each iteration of step (i) takes about 4 seconds. In one embodiment, each iteration of step (i) takes about 5 seconds. In one embodiment, each iteration of step (i) takes about 7 seconds. In one embodiment, each iteration of step (i) takes about 10 seconds. In one embodiment, each iteration of step (i) takes about 15 seconds. In one embodiment, each iteration of step (i) takes about 20 seconds. In one embodiment, each iteration of step (i) takes about 30 seconds. In one embodiment, each iteration of step (i) takes about 40 seconds. In one embodiment, each iteration of step (i) takes about 50 seconds. In one embodiment, each iteration of step (i) takes about 60 seconds.

In one embodiment of the disclosed and claimed subject matter, each iteration of step (iii) can take between about 0.1 seconds and about 60 seconds. In one embodiment of the disclosed and claimed subject matter, each iteration of step (iii) can take between about 20 seconds and about 60 seconds. In one embodiment of the disclosed and claimed subject matter, each iteration of step (iii) can take between about 5 seconds and about 20 seconds. In one embodiment of the disclosed and claimed subject matter, each iteration of step (iii) can take between about 1 second and about 5 seconds. In one embodiment, each iteration of step (iii) can take between about 0.2 seconds and about 0.9 second. In one embodiment, each iteration of step (iii) can take between about 0.3 seconds and about 0.8 second. In one embodiment, each iteration of step (iii) can take between about 0.4 seconds and about 0.7 second. In one embodiment, each iteration of step (iii) takes about 0.1 seconds. In one embodiment, each iteration of step (iii) takes about 0.2 seconds. In one embodiment, each iteration of step (iii) takes about 0.3 seconds. In one embodiment, each iteration of step (iii) takes about 0.4 seconds. In one embodiment, each iteration of step (iii) takes about 0.5 seconds. In one embodiment, each iteration of step (iii) takes about 0.6 seconds. In one embodiment, each iteration of step (iii) takes about 0.7 seconds. In one embodiment, each iteration of step (iii) takes about 0.8 seconds. In one embodiment, each iteration of step (iii) takes about 0.9 seconds. In one embodiment, each iteration of step (iii) takes about 1 second. In one embodiment, each iteration of step (iii) takes about 2 seconds. In one embodiment, each iteration of step (iii) takes about 3 seconds. In one embodiment, each iteration of step (iii) takes about 4 seconds. In one embodiment, each iteration of step (iii) takes about 5 seconds. In one embodiment, each iteration of step (iii) takes about 7 seconds. In one embodiment, each iteration of step (iii) takes about 10 seconds. In one embodiment, each iteration of step (iii) takes about 15 seconds. In one embodiment, each iteration of step (iii) takes about 20 seconds. In one embodiment, each iteration of step (iii) takes about 30 seconds. In one embodiment, each iteration of step (iii) takes about 40 seconds. In one embodiment, each iteration of step (iii) takes about 50 seconds. In one embodiment, each iteration of step (iii) takes about 60 seconds.

In one embodiment, each iteration of step (i) in a cycle takes about the same amount of time. In one embodiment, one or more iteration of step (i) in a cycle takes a different amount of time than another iteration of step (i) in the cycle.

In one embodiment, each iteration of step (iii) in a cycle takes about the same amount of time. In one embodiment, one or more iteration of step (iii) in a cycle takes a different amount of time than another iteration of step (iii) in the cycle.

In one embodiment, each iteration of step (i) in a cycle takes about the same amount of time as each iteration of step (iii) in the cycle. In one embodiment, each iteration of step (i) in a cycle takes a different amount of time as each iteration of step (iii) in the cycle.

### Exemplary Description of a Cycle

In one embodiment, for example, one cycle would include six (6) 0.4 second step (i) doses of SOCl₂ and pyridine followed by six (6) 0.2 second step (iii) of Hhfac. This cycle could be described as “6(0.4 s SOCl₂-Py)/6(0.2 s Hhfac).”

In one embodiment, for example, one cycle would include a step (i) pulse of a quantity of SOCl₂ vapor, a step (iA) pulse of a quantity of pyridine vapor, and a step (iii) pulse of a quantity of Hhfac vapor.

### Metals

As noted above, the disclosed and claimed process provides selective thermal etching on certain metal substrates. In one embodiment, the disclosed and claimed process etches a substrate including one or more of cobalt, nickel, copper, molybdenum, ruthenium, and tungsten. In one embodiment, the disclosed and claimed process etches a substrate including cobalt. In one embodiment, the disclosed and claimed process etches a substrate including nickel. In one embodiment, the disclosed and claimed process etches a substrate including copper. In one embodiment, the disclosed and claimed process etches a substrate including molybdenum. In one embodiment, the disclosed and claimed process etches a substrate including ruthenium. In one embodiment, the disclosed and claimed process etches a substrate including tungsten.

### Chamber (Reactor) Pressure

### SOCl₂ Pressures

In one embodiment, the SOCl₂ is delivered into the chamber from one port while an inert gas is delivered into the chamber though the same port. In one embodiment, SOCl₂ is delivered into the chamber from one port while an inert gas is delivered into the chamber from another port. In one embodiment, the SOCl₂ is delivered by flowing inert gas through the halogenating agent, forming a mixed vapor. In one embodiment, the SOCl₂ is delivered neat. In one embodiment, the total pressure in the chamber during the SOCl₂ delivery is from about 0.1 Torr to about 1.0 Torr. In one embodiment, the total pressure in the chamber during the SOCl₂ delivery is from about 0.5 Torr to about 5.0 Torr. In one embodiment, the total pressure in the chamber during the SOCl₂ delivery is from about 0.5 Torr to about 2.0 Torr. In one embodiment, the total pressure in the chamber during the SOCl₂ delivery is from about 0.5 Torr to about 1.0 Torr. In one embodiment, the total pressure in the chamber during the SOCl₂ delivery is from about 0.5 Torr to about 0.75 Torr. In one embodiment, the total pressure in the chamber during the SOCl₂ delivery is from about 1.0 Torr to about 5.0 Torr. In one embodiment, the total pressure in the chamber during the SOCl₂ delivery is from about 1.0 Torr to about 10.0 Torr. In one embodiment, the total pressure in the chamber during the SOCl₂ delivery is from about 2.0 Torr to about 10.0 Torr. In one embodiment, the total pressure in the chamber during the SOCl₂ delivery is from about 10.0 Torr to about 25.0 Torr. In one embodiment, the total pressure in the chamber during the SOCl₂ delivery is from about 10.0 Torr to about 50.0 Torr. In one embodiment, the total pressure in the chamber during the SOCl₂ delivery is from about 25.0 Torr to about 50.0 Torr. In one embodiment, the total pressure in the chamber during the SOCl₂ delivery is from about 50.0 Torr to about 75.0 Torr. In one embodiment, the total pressure in the chamber during the SOCl₂ delivery is from about 75.0 Torr to about 100.0 Torr. In one embodiment, the total pressure in the chamber during the SOCl₂ delivery is from about 1.0 Torr to about 100.0 Torr. In one embodiment, the total pressure in the chamber during the SOCl₂ delivery is from about 10.0 Torr to about 100.0 Torr.

### Delivery Method

In one embodiment, the SOCl₂ is delivered by vapor-draw. In one embodiment, the SOCl₂ is delivered by flowing an inert gas through the container of the SOCl₂.

### Steps (ii) and (iv) Purging

### Purge Gas

When performing step (ii) and/or step (iv), any suitable inert purge gas can be used. In one embodiment, the purge gas includes argon. In one embodiment, the purge gas includes nitrogen.

In one embodiment, the purge gas in step (ii) and step (iv) is the same. In one embodiment, the purge gas in step (ii) and step (iv) is different.

### Time

In one embodiment, the step (ii) and/or step (iv) purge time is from about 0.5 seconds to about 10 seconds. In one embodiment, the step (ii) and/or step (iv) purge time exposure is from about 1 second to about 7 seconds. In one embodiment, the step (ii) and/or step (iv) purge time exposure is from about 7 seconds to about 10 seconds. In one embodiment, the step (ii) and/or step (iv) purge time exposure is from about 10 seconds to about 20 seconds. In one embodiment, the step (ii) and/or step (iv) purge time exposure is from about 20 seconds to about 30 seconds. In one embodiment, the step (ii) and/or step (iv) purge time exposure is from about 30 seconds to about 60 seconds. In one embodiment, the step (ii) and/or step (iv) purge time exposure is about 0.25 seconds. In one embodiment, the step (ii) and/or step (iv) purge time exposure is about 0.5 seconds. In one embodiment, the step (ii) and/or step (iv) purge time exposure is about 1 second. In one embodiment, the step (ii) and/or step (iv) purge time exposure is about 2 seconds. In one embodiment, the step (ii) and/or step (iv) purge time exposure is about 3 seconds. In one embodiment, the step (ii) and/or step (iv) purge time exposure is about 4 seconds. In one embodiment, the step (ii) and/or step (iv) purge time exposure is about 5 seconds. In one embodiment, the step (ii) and/or step (iv) purge time exposure is about 6 seconds. In one embodiment, the step (ii) and/or step (iv) purge time exposure is about 7 seconds. In one embodiment, the step (ii) and/or step (iv) purge time exposure is about 8 seconds. In one embodiment, the step (ii) and/or step (iv) purge time exposure is about 9 seconds. In one embodiment, the step (ii) and/or step (iv) purge time exposure is about 10 seconds. In one embodiment, the step (ii) and/or step (iv) purge time exposure is about 12 seconds. In one embodiment, the step (ii) and/or step (iv) purge time exposure is about 15 seconds. In one embodiment, the step (ii) and/or step (iv) purge time exposure is about 17 seconds. In one embodiment, the step (ii) and/or step (iv) purge time exposure is about 20 seconds. In one embodiment, the step (ii) and/or step (iv) purge time exposure is about 25 seconds. In one embodiment, the step (ii) and/or step (iv) purge time exposure is about 30 seconds. In one embodiment, the step (ii) and/or step (iv) purge time exposure is about 40 seconds. In one embodiment, the step (ii) and/or step (iv) purge time exposure is about 50 seconds. In one embodiment, the step (ii) and/or step (iv) purge time exposure is about 60 seconds.

In one embodiment, the purge gas in step (ii) and step (iv) is flowed for the same amount of time. In one embodiment, the purge gas in step (ii) and step (iv) is flowed for a different amount of time.

### Flow Rate

When performing step (ii) and/or step (iv), the purge gas is flowed at between about 1 sccm to about 2000 sccm. In one embodiment, the step (ii) and/or step (iv) purge gas is flowed at between about 3 sccm to about 8 sccm. In one embodiment, the step (ii) and/or step (iv) purge gas is flowed at between about 50 sccm to about 500 sccm. In one embodiment, the step (ii) and/or step (iv) purge gas is flowed at between about 500 sccm to about 2000 sccm. In one embodiment, the step (ii) and/or step (iv) purge gas is flowed at about 1 sccm. In one embodiment, the step (ii) and/or step (iv) purge gas is flowed at about 2 sccm. In one embodiment, the step (ii) and/or step (iv) purge gas is flowed at about 3 sccm. In one embodiment, the step (ii) and/or step (iv) purge gas is flowed at about 4 sccm. In one embodiment, the step (ii) and/or step (iv) purge gas is flowed at about 5 sccm. In one embodiment, the step (ii) and/or step (iv) purge gas is flowed at about 6 sccm. In one embodiment, the step (ii) and/or step (iv) purge gas is flowed at about 7 sccm. In one embodiment, the step (ii) and/or step (iv) purge gas is flowed at about 8 sccm. In one embodiment, the step (ii) and/or step (iv) purge gas is flowed at about 9 sccm. In one embodiment, the step (ii) and/or step (iv) purge gas is flowed at about 10 sccm. In one embodiment, the step (ii) and/or step (iv) purge gas is flowed at about 9 sccm. In one embodiment, the step (ii) and/or step (iv) purge gas is flowed at about 10 sccm. In one embodiment, the step (ii) and/or step (iv) purge gas is flowed at about 50 sccm. In one embodiment, the step (ii) and/or step (iv) purge gas is flowed at about 100 sccm. In one embodiment, the step (ii) and/or step (iv) purge gas is flowed at about 200 sccm. In one embodiment, the step (ii) and/or step (iv) purge gas is flowed at about 300 sccm. In one embodiment, the step (ii) and/or step (iv) purge gas is flowed at about 500 sccm. In one embodiment, the step (ii) and/or step (iv) purge gas is flowed at about 750 sccm. In one embodiment, the step (ii) and/or step (iv) purge gas is flowed at about 1000 sccm. In one embodiment, the step (ii) and/or step (iv) purge gas is flowed at about 1250 sccm. In one embodiment, the step (ii) and/or step (iv) purge gas is flowed at about 1500 sccm. In one embodiment, the step (ii) and/or step (iv) purge gas is flowed at about 1750 sccm. In one embodiment, the step (ii) and/or step (iv) purge gas is flowed at about 2000 sccm.

In one embodiment, the purge gas in step (ii) and step (iv) is flowed at the same rate. In one embodiment, the purge gas in step (ii) and step (iv) is flowed at a different rate.

### Films

The disclosed and claimed subject matter further includes films prepared by the methods described herein.

In one embodiment, the films etched by the methods described herein have trenches, vias or other topographical features with an aspect ratio of about 0 to about 60. In a further aspect of this embodiment, the aspect ratio is about 0 to about 0.5. In a further aspect of this embodiment, the aspect ratio is about 0.5 to about 1. In a further aspect of this embodiment, the aspect ratio is about 1 to about 50. In a further aspect of this embodiment, the aspect ratio is about 1 to about 40. In a further aspect of this embodiment, the aspect ratio is about 1 to about 30. In a further aspect of this embodiment, the aspect ratio is about 1 to about 20. In a further aspect of this embodiment, the aspect ratio is about 1 to about 10. In a further aspect of this embodiment, the aspect ratio is about 0.1. In a further aspect of this embodiment, the aspect ratio is about 0.2. In a further aspect of this embodiment, the aspect ratio is about 0.3. In a further aspect of this embodiment, the aspect ratio is about 0.4. In a further aspect of this embodiment, the aspect ratio is about 0.5. In a further aspect of this embodiment, the aspect ratio is about 0.6. In a further aspect of this embodiment, the aspect ratio is about 0.8. In a further aspect of this embodiment, the aspect ratio is about 1. In a further aspect of this embodiment, the aspect ratio is greater than about 1. In a further aspect of this embodiment, the aspect ratio is greater than about 2. In a further aspect of this embodiment, the aspect ratio is greater than about 5. In a further aspect of this embodiment, the aspect ratio is greater than about 10. In a further aspect of this embodiment, the aspect ratio is greater than about 15. In a further aspect of this embodiment, the aspect ratio is greater than about 20. In a further aspect of this embodiment, the aspect ratio is greater than about 30. In a further aspect of this embodiment, the aspect ratio is greater than about 40. In a further aspect of this embodiment, the aspect ratio is greater than about 50. In a further aspect of the forgoing embodiments and aspects thereof, the metal includes cobalt, nickel, copper, molybdenum, ruthenium, and tungsten. In a further aspect of the forgoing embodiments and aspects thereof, the metal includes cobalt. In a further aspect of the forgoing embodiments and aspects thereof, the metal includes nickel. In a further aspect of the forgoing embodiments and aspects thereof, the metal includes copper. In a further aspect of the forgoing embodiments and aspects thereof, the metal includes molybdenum. In a further aspect of the forgoing embodiments and aspects thereof, the metal includes ruthenium. In a further aspect of the forgoing embodiments and aspects thereof, the metal includes tungsten.

In another embodiment, the films etched by the methods described herein have a resistivity of between about 1 μΩ.cm to about 250 μΩ.cm. In a further aspect of this embodiment, the films have a resistivity of about 1 μΩ.cm to about 5 μΩ.cm. In a further aspect of this embodiment, the films have a resistivity of about 3μΩ.cm to about 4 μΩ.cm. In a further aspect of this embodiment, the films have a resistivity of about 5 μΩ.cm to about 10 μΩ.cm. In a further aspect of this embodiment, the films have a resistivity of about 10 μΩ.cm to about 50 μΩ.cm. In a further aspect of this embodiment, the films have a resistivity of about 50 μΩ.cm to about 100 μΩ.cm. In a further aspect of this embodiment, the films have a resistivity of about 100μΩ.cm to about 250 μΩ.cm. In a further aspect of this embodiment, the films have a resistivity of about 1 μΩ.cm. In a further aspect of this embodiment, the films have a resistivity of about 2 μΩ.cm. In a further aspect of this embodiment, the films have a resistivity of about 3 μΩ.cm. In a further aspect of this embodiment, the films have a resistivity of about 4 μΩ.cm. In a further aspect of this embodiment, the films have a resistivity of about 5 μΩ.cm. In a further aspect of this embodiment, the films have a resistivity of about 7.5 μΩ.cm. In a further aspect of this embodiment, the films have a resistivity of about 10 μΩ.cm. In a further aspect of this embodiment, the films have a resistivity of about 15 μΩ.cm. In a further aspect of this embodiment, the films have a resistivity of about 20 μΩ.cm. In a further aspect of this embodiment, the films have a resistivity of about 30 μΩ.cm. In a further aspect of this embodiment, the films have a resistivity of about 40 μΩ.cm. In a further aspect of this embodiment, the films have a resistivity of about 50 μΩ.cm. In a further aspect of this embodiment, the films have a resistivity of about 60 μΩ.cm. In a further aspect of this embodiment, the films have a resistivity of about 80 μΩ.cm. In a further aspect of this embodiment, the films have a resistivity of about 100 μΩ.cm. In a further aspect of this embodiment, the films have a resistivity of about 150 μΩ.cm. In a further aspect of this embodiment, the films have a resistivity of about 200 μΩ.cm. In a further aspect of this embodiment, the films have a resistivity of about 250 μΩ.cm.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

For Examples 1 through 5, etching processes were carried out in a warm-walled chamber system. The system includes a processing chamber, equipped with an in-situ multi-wavelength ellipsometer, a load lock and an ultrahigh vacuum analysis chamber, equipped with Auger electron spectroscope (AES). The samples are introduced into the system on a 2-inch stainless steel puck, which can be transferred between the chambers using linear transfer arms. During processing the sample was heated to a constant temperature using two PID-controlled halogen lamps. Argon (99.999% purity, Arc3 gases) were used as a carrier and purge gas at a flow rate of 95 sccm, as set by mass-flow controllers. The processing chamber was pumped out using a turbo pump (Seiko-Seiki STP-300C) and a backing pump (Alcatel 2021a) with a throttle valve located before the turbo pump used to control the operating pressure, which was set at 400 m Torr. Thionyl Chloride (SOCl₂) and pyridine were obtained from Millipore Sigma.

For Examples 6 through 10, ALE processes were conducted in an ALD system with a showerhead lid heated to 130° C. This ALD system has capability to accommodate up to 300 mm diameter wafer sizes. This ALD system has a heated pedestal upon which the wafer is disposed. For each experiment, a 44 mm×44 mm test substrate was disposed on a 300 mm silicon carrier wafer. The pedestal was heated to a temperature of about 10-20 degrees C. higher than the intended sample temperature to accommodate for a temperature gradient through the carrier wafer. Thionyl chloride (SOCl₂), pyridine, and hexafluoroacetylacetone (Hhfac) were obtained from Millipore Sigma. All chemicals were dosed by pulsing vapor from ampules set to 30 degrees C. All chemicals were dosed into the ALD system one at a time, i.e. no chemicals were dosed simultaneously. During chemical dosing, chemicals were diluted in an argon purge flow of 400-600 sccm, and the ALD chamber pressure was maintained at 2000 mTorr. After each chemical dose, the chamber was purged with about 2000 sccm of argon for 60 seconds. Film thicknesses were measured using X-ray fluorescence.

### Example 1: SOCl₂ (Alone) vs. Pyridine (Alone) vs. SOCl₂+Pyridine

Surface changes of Co were compared between co-dosing of SOCl₂ and pyridine versus exposures to SOCl₂ or pyridine each alone at 250° C. Surface changes of Co upon reactant exposures were monitored by tracking the delta parameter measured at 635 nm from in situ spectroscopic ellipsometry. The tested Co substrates had a 30 nm layer of Co sputtered on a 3 nm TaN adhesion layer on Si. Co substrates of ˜1.5 cm×1.5 cm were used the experiments without surface cleaning. Sub-doses of 0.4 s SOCl₂ and pyridine co-dosing (SOCl₂-Py) were used.

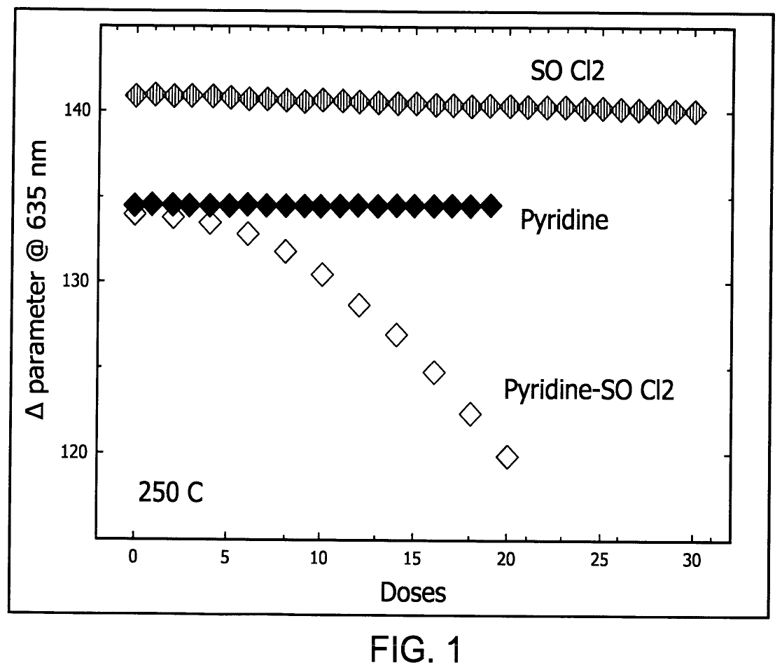

The starting delta parameter of Co substrates varied between about 135 and about 142, which might be due to the presence of impurities and surface cobalt oxide layers. As shown in FIG. 1, the delta parameter (Δ; measured at 635 nm) did not change after exposures of either SOCl₂ (30 sub-doses) or pyridine (320 sub-doses) alone whereas co-dosing of SOCl₂ and pyridine (20 sub-doses) resulted in a significant decrease in the delta parameter, from about 135 to about 120. These results indicate that no reaction took place on the Co substrates when dosing SOCl₂ or pyridine alone. On the other hand, this data establishes that an unexpectedly large decrease in delta parameter occurs upon co-dosing of SOCl₂ and pyridine (i.e., that the Co surface was reactive towards a co-dose of SOCl₂ and pyridine despite not being reactive to either SOCl₂ or pyridine individually).

### Example 2: Other Chlorinating Agents

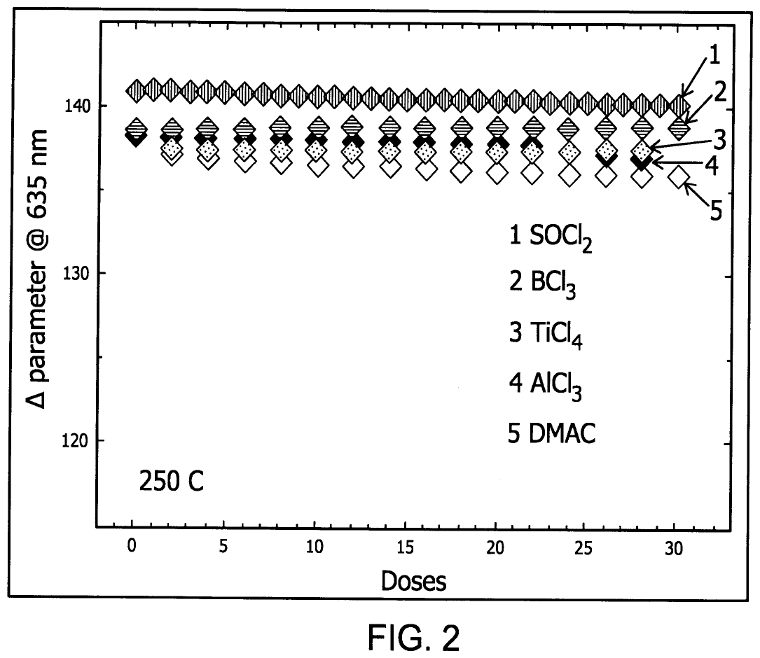

As shown in FIG. 2, other known chlorinating agents were analyzed under similar conditions (e.g., at 250° C.) to determine whether they would surface chlorinate the Co surfaces. The tested agents included: BCl₃, TiCl₄, AlCl₃ and Al(CH₃)₂Cl. In FIG. 2, it can be seen that there were no significant changes in the delta parameter (Δ; measured at 635 nm) after 30 doses of each of BCl₃, TiCl₄, Al(CH₃)₂Cl and AlCl₃ respectively. This data indicates that the Co surface was unreactive towards BCl₃, TiCl₄, AlCl₃ and Al(CH₃)₂Cl.

### Example 3: Cobalt Chlorination by SOCl₂+Pyridine

In-situ Auger electron spectroscopy (AES) was used to analyze surface chemical changes after co-dosing of SOCl₂ and pyridine at 250° C. Elemental composition was measured in atomic percent (at. %) from the in-situ AES for the Co before and after SOCl₂-Py exposure (Table 1). In Table 1, the as-received Co surface showed about 36 at. % of Co and 38 at. % of oxygen (O) due to the presence of surface cobalt oxide, 21 at. % of carbon (C) derived from to adventitious carbon or impurities, as well as 5 at. % of chlorine (Cl). After 10 sub-doses of SOCl₂-Py, the Cl at. % showed a marked increase from 5 to 32 at. %. The increase in Cl content confirmed chlorination of Co upon exposures to SOCl₂-Py.

TABLE 1
Elemental composition from in situ AES showing atomic percent (at.
%) of Co, Cl, O, C and Ta for as-received Co and Co after exposure to
ten (10) 0.4 second sub-doses of SOCl₂—Py at 250° C.

| | Co (at. %) | Cl (at. %) | O (at. %) | C (at. %) | Ta (at. %) |
|---|---|---|---|---|---|
| as-received | 36 | 5 | 38 | 21 | 0 |
| Co | | | | | |
| 10 | 29 | 34 | 24 | 13 | 0 |
| (SOCl2—py) | | | | | |

### Example 4: Cobalt ALE Using SOCl₂+pyridine and Hhfac

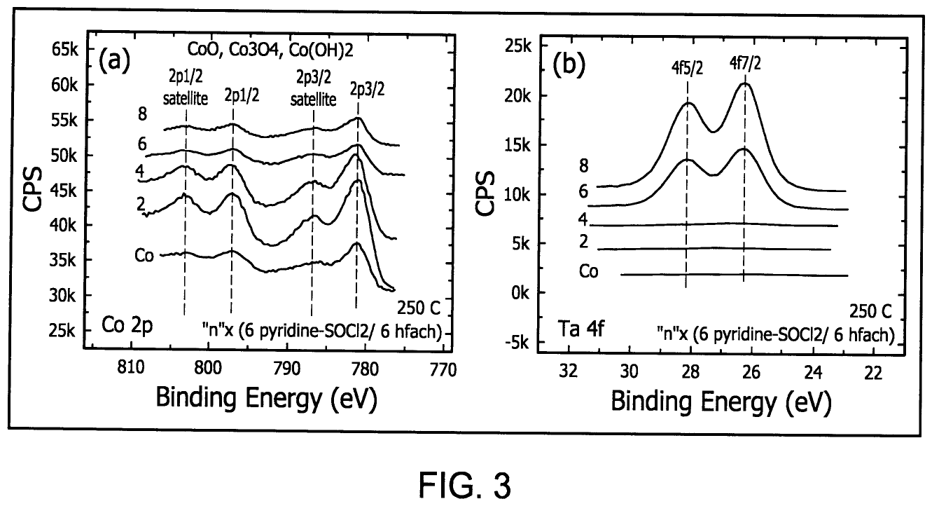

Chemical analysis using ex situ X-ray photoelectron spectroscopy (XPS) was performed to determine etching of Co after varied etch cycles at 250° C. An etch cycle would proceed with six (6) 0.4 second sub-doses of SOCl₂ and pyridine co-dosing (SOCl₂-Py) followed by six (6) 0.2 second sub-doses of Hhfac (etch cycle exposure sequence 6(0.4 s SOCl₂-Py)/6(0.2 s Hhfac)). High resolution scans for Co 2p and Ta 4f are displayed in FIG. 3 after 2, 4, 6 and 8 etch cycles at 250° C. All Co samples showed Co peaks centered at about 797 and 781 eV that were derived from CoOₓ (FIG. 3a). As the number of etch cycles increased, the Co peak intensity decreased. In addition, Ta peaks located at 26.5 and 28.2 eV appeared after 6 or more etch cycles applied (FIG. 3b). The reduction in Co signals accompanied by the appearance of Ta signals confirmed removal of Co films due to etching.

### Example 5: Cobalt ALE Using SOCl₂+pyridine and Hhfac

Table 2 summarizes the measured effect/dependence of temperature on etching of Co using in-situ AES. The elemental composition of Co substrates after 6 etch cycles at 140° C., 170° C., 250° C. and 275° C., respectively, were analyzed (etch cycle exposure sequence 6(0.4 s SOCl₂-Py)/6(0.2 s Hhfac). At 250° C. and 275° C., the sample showed about 2 to 0 at. % of Co after 6 etch cycles, indicating that the Co film was mostly removed while the Ta intensity was about 18 to about 19 at. %. However, the amount of Co left increased to 24 at. % as the temperature decreased to 140° C. This indicated that less Co was removed at lower temperatures and etch process was therefore temperature dependent.

TABLE 2
Elemental composition from in situ AES showing atomic
percent (at. %) of Co, Cl, O, C and Ta for Co after
6 etch cycles at temperatures from 140° C. to 275° C.

| Temperature | Co (at. %) | Cl (at. %) | O (at. %) | C (at. %) | Ta (at. %) |
|---|---|---|---|---|---|
| 140° C. | 24 | 62 | 8 | 6 | 0 |
| 170° C. | 21 | 55 | 13 | 10 | 0 |
| 250° C. | 2 | 8 | 13 | 43 | 19 |
| 275° C. | 0 | 6 | 19 | 46 | 18 |

### Example 6: Cobalt ALE Using SOCl₂, Pyridine, and/or Hhfac

In each experiment in this example, the sample was a 44 mm×44 mm silicon sample which was coated with approx. 166-182 Å of Co by physical vapor deposition (PVD). The initial resistivity of Co was approx. 28-33 μohm-cm. In this example, the pedestal temperature was set at 270° C. for an approximate sample temperature of 260° C.

Each Co sample was loaded into the ALD system on a 300 mm silicon carrier wafer and subjected to 20 ALE cycles. Each cycle consisted of sequential doses of two or three of the following chemicals: thionyl chloride, pyridine, and/or Hhfac. The ALD system was purged with argon after each dose. An additional experiment was performed using a process identical to a 3-step process, except only the argon carrier gas was dosed into the ALD system, to assess the effect of process conditions (i.e., temperature) on the Co film. Results are summarized in Table 3 below. No etch is observed for processes that do not include both SOCl₂ and Hhfac. The SOCl₂/pyridine/Hhfac process yields the greatest etch, whereas the pyridine/SOCl₂/Hhfac process shows similar results as the SOCl₂/Hhfac process. There is no significant difference in resistivity for samples that were exposed to any etch chemistry vs. the sample processed in argon alone. However, all processes showed a significant decrease in resistivity vs. the unprocessed Co.

TABLE 3
Results from Co ALE experiments. Each experiment consisted
of a first dose, a second dose, and in some cases also a third
dose, repeated 20 times, with purges between each dose.

| | | | Co thickness | Co resistivity after |
|---|---|---|---|---|
| First dose | Second dose | Third dose | change (Å) | process (μohm-cm) |
| Pyridine | SOCl₂ | Hhfac | −11 ± 2 | 23.2 ± 3.4 |
| SOCl₂ | Pyridine | Hhfac | −15 ± 2 | 19.7 ± 0.5 |
| SOCl₂ | Hhfac | None | −10 ± 2 | 19.8 ± 1.2 |
| Pyridine | Hhfac | None | No change | 20.2 ± 0.5 |
| SOCl₂ | Pyridine | None | No change | 21.0 ± 0.3 |
| Argon | Argon | Argon | No change | 20.9 ± 2.1 |

### Example 7: Cobalt ALE Using SOCl₂ and Hhfac

In each experiment in this example, the sample was a 44 mm×44 mm silicon sample which was coated with approx. 169-209 Å of Co by physical vapor deposition (PVD). The initial resistivity of Co was approx. 28-33 μohm-cm. In this example, the pedestal temperature was set at 210, 240, or 270° C. for an approximate sample temperature of 200, 230, or 260° C., respectively.

Each Co sample was loaded into the ALD system on a 300 mm silicon carrier wafer and subjected to 20, 40, or 60 ALE cycles. Each cycle consisted of sequential doses of thionyl chloride and Hhfac. The ALD system was purged with argon after each dose. Results are summarized in Table 4 below. Significant Co etch is observed for sample temperature as low as 200° C. The amount of Co etch increases with temperature and cycle count. Linear fits to the Co thickness change vs. cycle count yield an etch per cycle of about 1.2 Å/cycle after a delay of about 32 cycles at 230° C., and about 3.0 Å/cycle after a delay of about 16 cycles at 260° C. The resistivity is lower than pre-ALE values for samples with etch up to about 13 Å. However, samples with greater etch show increasing resistivity with etch amount. The sample processed at 260° C. for 60 cycles shows the greatest etch (129±2 Å) with incomparably high resistivity vs. the other samples in Table 4.

TABLE 4
Results from Co ALE experiments. Each experiment consisted
of several cycles of a first dose of SOCl₂ and a second
dose of Hhfac, with purges between each dose.

| Sample | Number of ALE | Co thickness | Co resistivity after |
|---|---|---|---|
| temperature (° C.) | cycles | change (Å) | process (μohm-cm) |
| 200 | 40 | −8 ± 2 | 24.8 ± 0.1 |
| 230 | 40 | −11 ± 2 | 20.9 ± 0.1 |
| 230 | 60 | −32 ± 2 | 27.6 ± 5.0 |
| 230 | 80 | −59 ± 2 | 33.6 ± 8.5 |
| 260 | 20 | −10 ± 2 | 19.8 ± 1.2 |
| 260 | 40 | −79 ± 2 | 49.8 ± 9.9 |
| 260 | 60 | −129 ± 2 | >1,000 |

### Example 8: Cobalt ALE Using SOCl₂, Pyridine, and Hhfac

In each experiment in this example, the sample was a 44 mm×44 mm silicon sample which was coated with approx. 169-207 Å of Co by physical vapor deposition (PVD). The initial resistivity of Co was approx. 28-33 μohm-cm. In this example, the pedestal temperature was set at 210, 240, or 270° C. for an approximate sample temperature of 200, 230, or 260° C., respectively.

Each Co sample was loaded into the ALD system on a 300 mm silicon carrier wafer and subjected to 20, 40, or 60 ALE cycles. Each cycle consisted of sequential doses of thionyl chloride, followed by pyridine, followed by Hhfac. The ALD system was purged with argon after each dose. Results are summarized in Table 5 below. Significant Co etch is observed for sample temperature as low as 230° C. The amount of Co etch generally increases with temperature and cycle count. For samples etched at 230° C. with either 40 or 60 ALE cycles, the etch amount is identical; this could be ascribed to effects relating to a native oxide on the Co surface, or non-uniformity between samples. Linear fits to the Co thickness change vs. cycle count yield an etch per cycle of about 1.2 Å/cycle after a delay of about 26 cycles at 230° C., and about 3.7 Å/cycle after a delay of about 15 cycles at 260° C. The resistivity is lower than pre-ALE values for samples with etch up to about 25 Å. However, samples with greater etch show increasing resistivity with etch amount. The samples processed at 260° C. for 40 cycles or 60 cycles show the greatest etch (97±2 Å or 163±2 Å, respectively) with incomparably high resistivities vs. the other samples in Table 5.

TABLE 5
Results from Co ALE experiments. Each experiment consisted of
several cycles of a first dose of SOCl₂, a second dose of pyridine,
and a third dose of Hhfac, with purges between each dose.

| Sample | Number of ALE | Co thickness | Co resistivity after |
|---|---|---|---|
| temperature (° C.) | cycles | change (Å) | process (μohm-cm) |
| 200 | 40 | −3 ± 2 | 23.4 ± 0.2 |
| 230 | 40 | −25 ± 2 | 20.9 ± 0.8 |
| 230 | 60 | −25 ± 2 | 23.0 ± 0.5 |
| 230 | 80 | −73 ± 2 | 43.1 ± 22.4 |
| 260 | 20 | −15 ± 2 | 19.7 ± 0.5 |
| 260 | 40 | −97 ± 2 | >1,000 |
| 260 | 60 | −163 ± 2 | >1,000 |

### Example 9: Molybdenum ALE Using SOCl₂ and Hhfac

In each experiment in this example, the sample was a 44 mm×44 mm silicon sample which was coated with approx. 200 Å of Mo by physical vapor deposition (PVD). The initial resistivity of Mo was approx. 21-22 μohm-cm. In this example, the pedestal temperature was set at 210 or 270° C. for an approximate sample temperature of 200 or 260° C., respectively. Each Mo sample was loaded into the ALD system on a 300 mm silicon carrier wafer and subjected to 40 ALE cycles. Each cycle consisted of sequential doses of thionyl chloride and Hhfac. The ALD system was purged with argon after each dose.

After ALE at 200° C., there was no significant change in Mo thickness or resistivity.

After ALE at 260° C., approx. 9 Å of Mo was removed, and there was no significant change in Mo resistivity.

### Example 10: Molybdenum ALE Using SOCl₂, Pyridine, and Hhfac

In each experiment in this example, the sample was a 44 mm×44 mm silicon sample which was coated with approx. 200 Å of Mo by physical vapor deposition (PVD). The initial resistivity of Mo was approx. 21-22 μohm-cm. In this example, the pedestal temperature was set at 210 or 270° C. for an approximate sample temperature of 200 or 260° C., respectively.

Each Mo sample was loaded into the ALD system on a 300 mm silicon carrier wafer and subjected to 40 ALE cycles. Each cycle consisted of sequential doses of thionyl chloride, followed by pyridine, followed by Hhfac. The ALD system was purged with argon after each dose.

After ALE at 200° C., there was no significant change in Mo thickness or resistivity.

After ALE at 260° C., approx. 11 Å of Mo was removed, and there was no significant change in Mo resistivity.

### Summary of Examples

It has been demonstrated in Examples 1-5 that the combination of thionyl chloride (SOCl₂) and pyridine is used as a surface chlorination reagent for thermal ALE of Co. In-vacuum AES revealed that co-dosing with pyridine-SOCl₂ led to about 30 at. % Cl on the Co surface. In particular, surface changes of Co were compared between co-dosing of SOCl₂ and pyridine versus exposures to SOCl₂, pyridine and other known chlorinating agents each alone at 250° C. Surface changes of Co upon reactant exposures were monitored by tracking the delta parameter measured at 635 nm from in situ spectroscopic ellipsometry. Co-doses of SOCl₂ and pyridine showed marked decrease in delta values whereas no such changes were observed for the other tested materials.

In addition, in situ AES analysis revealed surface changes due to co-dosing while there was no change with comparative dosing with SOCl₂, pyridine or other known chlorinating agents alone. The removal of Co was confirmed with ex situ XPS where Co content decreased along with increase in Ta signal from the underlying TaN layer upon sequential exposures of SOCl₂-py/Hhfac. Moreover, the etching behavior using SOCl₂-py/Hhfac was demonstrated to be controllable viz. its temperature dependence.

Experiments using a 300 mm ALD reactor (Examples 6-10) show that Co can be controllably etched by cycling either SOCl₂ and Hhfac or by cycling SOCl₂, pyridine, and Hhfac. Etch does not occur if either SOCl₂ or Hhfac is not included in the ALE cycle. Etch per cycle values between about 1 Å/cycle to about 4 Å/cycle were achieved for sample temperatures of about 200° C. to about 260° C. Up to about 25 Å of Co was removed by this process without a significant change in Co resistivity. Mo could also be etched at 260° C. with no significant change in Mo resistivity. In most cases, processes using SOCl₂, pyridine, and Hhfac demonstrated greater etch than processes using SOCl₂ and Hhfac under otherwise similar etch conditions.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

What is claimed is:

1. A thermal ALE process performed in a reactor for selectively etching a metal substrate comprising the steps of:
(i) forming a chlorinated metal-containing layer on a surface of a metal by exposing the surface to a chlorinating agent,
(ii) conducting a first purge to remove any excess chlorinating agent and/or reaction products,
(iii) forming a volatile etch product on the surface of the metal by exposing the chlorinated metal-containing layer to at least one volatilizing agent; and
(iv) conducting a second purge to remove the volatile etch product.

2-4. (canceled)

5. The process of claim 1, wherein the chlorinating agent is formed by mixing thionyl chloride (SOCl₂) with pyridine.

6. (canceled)

7. (canceled)

8. The process of claim 1, wherein the chlorinating agent comprises thionyl chloride (SOCl₂).

9. The process of claim 1, wherein the metal comprises one or more of cobalt, nickel, copper, molybdenum, ruthenium, tungsten and alloys including the same.

10. The process of claim 1, wherein the chlorinated metal comprises one or more of cobalt, nickel, copper, molybdenum, ruthenium, tungsten and alloys including the same.

11-55. (canceled)

56. The process of claim 1, wherein step (i) is performed at temperature between about 100° C. and about 350° C.

57-91. (canceled)

92. The process of claim 1, wherein step (iii) is performed at temperature between about 100° C. and about 350° C.

93-127. (canceled)

128. The process of claim 1, wherein step (i) and step (iii) are performed at about the same temperature.

129. (canceled)

130. The process of claim 1, wherein step (i) and step (iii) are each performed at a different temperature.

131. A metal-containing film etched by the process of claim 1, wherein the film comprises one or more of cobalt, nickel, copper, molybdenum, ruthenium, tungsten and alloys including the same.
